(19) United States
(12) Patent Application Publication
(10) Pub. No.: US 2007/0158715 A1
(43) Pub. Date: Jul. 12, 2007

(54) Ferroelectric capacitor and method for fabricating the same

(76) Inventor: Shinichiro Hayashi, Osaka (JP)

Correspondence Address: MCDERMOTT WILL & EMERY LLP, 600 13TH STREET, N.W., WASHINGTON, DC, 20005-3096, US

(21) Appl. No.: 11/540,761

(22) Filed: Oct. 2, 2006

(30) Foreign Application Priority Data
Jan. 10, 2006 (JP) JP 2006-002121

(51) Int. Cl. H01L 29/94

(52) U.S. Cl. 257/295

(57) ABSTRACT

In a ferroelectric capacitor comprising: a lower electrode; a ferroelectric film formed on the lower electrode; and an upper electrode formed on the ferroelectric film, variations in composition profile of elements constituting the ferroelectric film are 50% or lower in the thickness direction of the ferroelectric film, and the polarization switching time of the ferroelectric film is 1 μs or less.

### BACKGROUND OF THE INVENTION

(a) Fields of the Inventions

The present invention relates to ferroelectric memory devices using dielectric materials, and to ferroelectric capacitors and their fabrication methods capable of enhancing the speed at which polarization of a ferroelectric film is reversed.

(b) Description of Related Art

In the development of ferroelectric memory devices, in order to fabricate the devices having stack structures with a large capacity of 256 kbit to 4 Mbit, a significant increase in degree of integration of the devices, that is, miniaturization of the devices is indispensable. Moreover, the devices are required to operate at high speed.

For example, a first conventional example (see, for example, Japanese Laid-open Patent Publication No. H7-99252) proposes the high-speed operation method as described below. In the case where a ferroelectric film made of PZT(PbZrₓ Ti₁₋ₓ O₃) with a ferroelectric crystal structure represented by ABO₃ (where A and B represent metal) is formed as a ferroelectric film used in a ferroelectric capacitor, a seed layer made of PTO is formed and then a ferroelectric film made of PZT is formed, thereby lowering the Curie temperature Tc. This prevents degradation in polarization switching characteristics of the ferroelectric capacitor and provides high-speed operation of the ferroelectric memory device.

As another example, a second conventional example (see, for example, Japanese Laid-open Patent Publication No. H9-25124 (Japanese Patent No. 3106913)) proposes the high-speed operation method as described below. In the case where a ferroelectric film made of SBT(SrBiTa₂O₉ ) with a bismuth-layered ferroelectric crystal structure is formed as a ferroelectric film used in a ferroelectric capacitor, Sr constituting the ferroelectric film can be substituted partially by Ba to decrease the coercive voltage, or Ta can be substituted partially by Nb to increase remanent polarization. By utilizing them, high-speed operation of the ferroelectric memory device is provided.

### SUMMARY OF THE INVENTION

In the first conventional example, since the Curie temperature Tc of the ferroelectric is lowered, the capacitor operates unstably at high temperatures. This in turn degrades the characteristics of retention or imprint reliabilities thereof Furthermore, precise composition control is required in order to set the temperature at a desired Curie temperature Tc. Moreover, the process stability is also unstable, and it is still difficult to fully prevent degradation in the stability.

In addition, from a detailed study, the inventors have found that a ferroelectric capacitor fabricated by the method of the first and second conventional examples has degraded polarization switching characteristics.

In view of the foregoing, an object of the present invention is to provide a ferroelectric capacitor and its fabrication method for producing a ferroelectric memory device capable of operating at high speed. Another object of the present invention is to provide a ferroelectric capacitor and its fabrication method for producing a ferroelectric memory device capable of operating with stability.

To attain the above object, the inventors eagerly conducted a thorough study on the first and second conventional examples mentioned above. As a result of this, it is found that a decrease in variations in composition profile of elements constituting the ferroelectric film of the ferroelectric capacitor, or a decrease in variations in orientation of grains forming the ferroelectric film can improve the polarization switching characteristics of the ferroelectric capacitor and fabricate a ferroelectric memory device capable of operating with stability.

In view of the above findings, a ferroelectric capacitor according to a first aspect of the present invention comprises: a lower electrode; a ferroelectric film formed on the lower electrode; and an upper electrode formed on the ferroelectric film. When variations in composition profile of elements constituting the ferroelectric film are 50% or lower in the thickness direction of the ferroelectric film, the polarization switching time of the ferroelectric film is 1 μs or less. This capacitor provides excellent polarization switching characteristics and stable operation.

In the ferroelectric capacitor according to the first aspect of the present invention, when variations in the composition profile are 25% or lower, the polarization switching time is 100 ns or less. Furthermore, when variations in the composition profile are 13% or lower, the polarization switching time is 20 ns or less. This capacitor provides excellent polarization switching characteristics and stable operation.

Next, a ferroelectric capacitor according to a second aspect of the present invention comprises: a lower electrode; a ferroelectric film formed on the lower electrode; and an upper electrode formed on the ferroelectric film. When variations in orientation of the ferroelectric film are 100% or lower, the polarization switching time of the ferroelectric film is 1 μs or less. This capacitor provides excellent polarization switching characteristics and stable operation.

In the ferroelectric capacitor according to the second aspect of the present invention, when variations in orientation of the ferroelectric film are 50% or lower, the polarization switching time of the ferroelectric film is 100 ns or less. Furthermore, when variations in orientation of the ferroelectric film are 20% or lower, the polarization switching time of the ferroelectric film is 20 ns or less. This capacitor provides excellent polarization switching characteristics and stable operation.

A ferroelectric capacitor according to a third aspect of the present invention comprises: a lower electrode; a ferroelectric film formed on the lower electrode; and an upper electrode formed on the ferroelectric film. Of elements constituting the ferroelectric film, the content of the element with a relatively high volatility has a smooth distribution in the thickness direction of the ferroelectric film, the content of the element with a relatively high volatility is locally minimum around the center of the thickness of the ferroelectric film, and the content of an element with a relatively high volatility is locally maximum around the interfaces between the ferroelectric film and the lower electrode and between the ferroelectric film and the upper electrode. This capacitor provides excellent polarization switching characteristics and stable operation.

As a concrete example of the structure of the ferroelectric capacitor according to the third aspect of the present invention, the ferroelectric film has a Pb-containing ferroelectric crystal structure represented by (Bi₂O₂)²⁺ (Aₘ₋₁BₘO₃ₘ₊₁)²⁻ (where A represents bivalent or trivalent metal, B represents quadrivalent or pentavalent metal, and m satisfies 2, 3, 4, or 5), and the element with a relatively high volatility is Pb.

As another concrete example of the structure of the ferroelectric capacitor according to the third aspect of the present invention, the ferroelectric film has a bismuth-layered ferroelectric crystal structure, and the element with a relatively high volatility is Bi.

A first method for fabricating a ferroelectric capacitor according to the third aspect of the present invention relates to a fabrication method of the above-described ferroelectric capacitor according to the third aspect of the present invention. The ferroelectric film has a Pb-containing ferroelectric crystal structure represented by (Bi₂O₂)²⁺ (Aₘ₋₁BₘO₃ₘ₊₁)²⁻ (where A represents bivalent or trivalent metal, B represents quadrivalent or pentavalent metal, and m satisfies 2, 3, 4, or 5), and the element with a relatively high volatility is Pb. Formation of the ferroelectric film comprises: a first step of forming, on the lower electrode, a first ferroelectric film containing a greater number of Pb in content than the stoichiometric content; a second step of forming, on the first ferroelectric film, a second ferroelectric film containing a smaller number of Pb in content than the stoichiometric content; and a third step of forming, on the second ferroelectric film, a third ferroelectric film containing a greater number of Pb in content than the stoichiometric content.

A second method for fabricating a ferroelectric capacitor according to the third aspect of the present invention relates to a fabrication method of the above-described ferroelectric capacitor according to the third aspect of the present invention. The ferroelectric film has a bismuth-layered ferroelectric crystal structure, and the element with a relatively high volatility is Bi. Formation of the ferroelectric film comprises: a first step of forming, on the lower electrode, a first ferroelectric film containing a greater number of Bi in content than the stoichiometric content; a second step of forming, on the first ferroelectric film, a second ferroelectric film containing a smaller number of Bi in content than the stoichiometric content; and a third step of forming, on the second ferroelectric film, a third ferroelectric film containing a greater number of Bi in content than the stoichiometric content.

With the first and second methods for fabricating a ferroelectric capacitor according to the third aspect of the present invention, variations in orientation of the ferroelectric film can be decreased, and thereby polarization switching characteristics of the ferroelectric film can be prevented from varying. The fabricated capacitor provides excellent polarization switching characteristics and stable operation.

In the first and second methods for fabricating a ferroelectric capacitor according to the third aspect of the present invention, after the third step, a thermal treatment is performed at a temperature higher than the crystallization temperatures of the first, second, and third ferroelectric films. Thereby, concentration gradient of Pb element or Bi element can be generated.

As shown above, the present invention can offer the ferroelectric capacitor which prevents degradation of ferroelectric materials during a semiconductor fabrication process, particularly a decrease in electric properties associated with miniaturization of semiconductors, and which conducts excellent high-speed operation-and stable operation.

### BRIEF DESCRIPTION OF THE DRAWINGS

FIGS. 1A to 1C are sectional views showing a method for fabricating a ferroelectric capacitor according to a first embodiment of the present invention in the order of its fabrication process steps.

FIGS. 2A and 2B are sectional views showing the method for fabricating a ferroelectric capacitor according to the first embodiment of the present invention in the order of its fabrication process steps.

FIG. 3A is a sectional view showing the thicknesswise profile of the ferroelectric capacitor according to the first embodiment of the present invention, and FIG. 3B is a sectional view showing the thicknesswise profile of the ferroelectric capacitor according to a conventional example.

FIG. 4 is a graph showing the relation between variations (%) in composition profile of elements constituting the ferroelectric film and the polarization switching speed (nanosecond) in the ferroelectric capacitor according to the first embodiment of the present invention.

FIGS. 5A to 5C are sectional views showing a fabrication method of a ferroelectric capacitor according to a second embodiment of the present invention in the order of its fabrication process steps.

FIGS. 6A and 6B are sectional views showing a fabrication method of a ferroelectric capacitor according to the second embodiment of the present invention in the order of its fabrication process steps.

FIG. 7 is a graph showing the relation between variations (%) in orientation and the polarization switching speed (nanosecond) of the ferroelectric film according to the second embodiment of the present invention.

FIGS. 8A to 8C are sectional views showing a fabrication method of a ferroelectric capacitor made of SBTN(SrBi₂(Ta₁₋ₓNbₓ)₂O₉) according to a third embodiment of the present invention in the order of its fabrication process steps.

FIGS. 9A and 9B are sectional views showing the fabrication method of a ferroelectric capacitor made of SBTN according to the third embodiment of the present invention in the order of its fabrication process steps.

FIGS. 10A to 10C are sectional views showing a fabrication method of a ferroelectric capacitor made of PZT according to the third embodiment of the present invention in the order of its fabrication process steps.

FIGS. 11A and 11B are sectional views showing the fabrication method of a ferroelectric capacitor made of PZT according to the third embodiment of the present invention in the order of its fabrication process steps.

FIGS. 12A to 12C are sectional views showing a fabrication method of a ferroelectric capacitor made of BLT according to the third embodiment of the present invention in the order of its fabrication process steps.

FIGS. 13A and 13B are sectional views showing the fabrication method of a ferroelectric capacitor made of BLT((Bi,La)₄Ti₃O₁₂) according to the third embodiment of the present invention in the order of its fabrication process steps.

### DETAILED DESCRIPTION OF THE PREFERRED EMBODIMENTS

Hereinafter, embodiments of the present invention will be described with reference to the accompanying drawings.

### First Embodiment

A ferroelectric capacitor and its fabrication method according to a first embodiment of the present invention will be described.

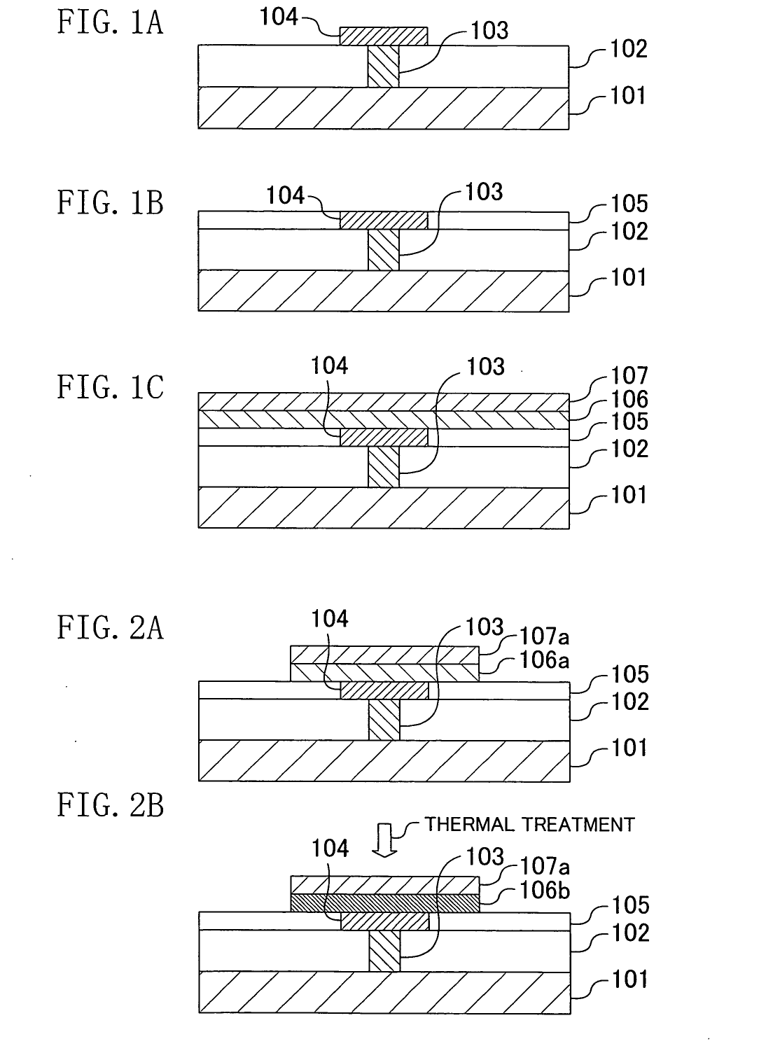

FIGS. 1A to 1C and 2A and 2B are sectional views showing a method for fabricating a ferroelectric capacitor according to the first embodiment of the present invention in the order of its fabrication process steps.

Referring to FIG. 1A, on a semiconductor substrate 101 with memory cell transistors (not shown) and the like formed thereon, a first interlayer insulating film 102 is formed which is made of, for example, a BPSG (SiO₂ with B, P, and the like added therein) film. Subsequently, the first interlayer insulating film 102 is formed with a contact plug 103 of tungsten, polysilicon, or the like whose bottom end reaches the top surface of the semiconductor substrate 101. Then, a lower electrode 104 made by sequentially stacking a barrier layer and a noble metal layer in this order is formed on the first interlayer insulating film 102. The barrier layer is composed of one or more layers selected from, for example, IrO, Ir, TiAlN, and TiN and functions as an oxygen barrier. The bottom surface of the barrier layer is connected to the top end of the contact plug 103. The noble metal layer promotes crystal growth of a ferroelectric film that will be described later. Note that the lower electrode 104 is patterned to cover the first contact plug 103.

Next, as shown in FIG. 1B, on the first interlayer insulating film 102, a buried insulating film made of SiO₂, O₃TEOS, or the like is formed to cover the lower electrode 104, and then CMP is carried out to expose the top surface of the lower electrode 104. Thereby, the buried insulating film 105 surrounding the lower electrode 104 is formed on the first interlayer insulating film 102. Although the lower electrode 104 is buried in the insulating film in the first embodiment, it is not limited to this structure.

As shown in FIG. 1C, a ferroelectric film 106 made of SBTN (SrBi₂(Ta_{1-b}Nb_{b})₂O₉) or the like and a conductive film 107 made of one or more layers selected from Pt, Ir, and IrO are sequentially formed from bottom to top on the lower electrode 104 and the buried insulating film 105. In this formation step, the ferroelectric film 106 is preferably formed by the following procedure. First, a first ferroelectric film is formed which contains a too large amount of relatively high volatile element of the elements constituting the ferroelectric film (at least so that the content of that element is greater than the stoichiometric content thereof), and on the first ferroelectric film, a second -ferroelectric film is formed which contains a too small amount of relatively high volatile element of the elements constituting the ferroelectric film (at least so that the content of that element is smaller than the stoichiometric content thereof). Finally, on the second ferroelectric film, a third ferroelectric film is formed which contains a too large amount of relatively high volatile element of the elements constituting the ferroelectric film (at least so that the content of that element is greater than the stoichiometric content thereof), thereby forming the ferroelectric film 106. Thereafter, calcination by rapid thermal processing (RTP) is performed for the purpose of producing nuclei serving as base points for crystal growth.

As shown in FIG. 2A, the ferroelectric film 106a and the conductive film 107 are patterned to form a ferroelectric film 106a covering the top surface of the lower electrode 104 and an upper electrode 107a. Although the ferroelectric film 106a and the conductive film 107 are patterned using the same mask in this step, the patterning may be conducted using different masks.

Next, as shown in FIG. 2B, a thermal treatment for crystallizing the ferroelectric film 106a is performed to form the crystallized ferroelectric film 106b. In the manner described above, a ferroelectric capacitor formed of the lower electrode 104, the ferroelectric film 106b, and the upper electrode 107a is fabricated. The above description has been made of the case where the thermal treatment is performed twice, specifically, immediately after coating of the ferroelectric film 106 (see FIG. 1C) and during the step shown in FIG. 2B. Alternatively, it is sufficient to perform the thermal treatment at least once in any one of steps after coating of the ferroelectric film 106. Although not shown, subsequent steps are carried out as follows. For example, a third interlayer insulating film is formed to cover the ferroelectric capacitor, and the third interlayer insulating film is formed with a second contact plug whose bottom end is connected to the top surface of the upper electrode 107a. Then, on the third interlayer insulating film, an interconnect (a bit line) made of an Al/TiN/Ti stacked film is formed whose bottom surface is connected to the top end of the second contact plug.

As described above, with the first embodiment of the present invention, deficiency of high volatile element can be prevented from being produced in the ferroelectric by diffusion of that element from the ferroelectric film, and the resulting deficiency of other elements can be prevented from being produced in the ferroelectric film. Therefore, the thicknesswise profile of composition of the element constituting the ferroelectric film of the ferroelectric capacitor can be made uniform.

Herein, the effects exerted by the first embodiment of the present invention will be described in a concrete manner.

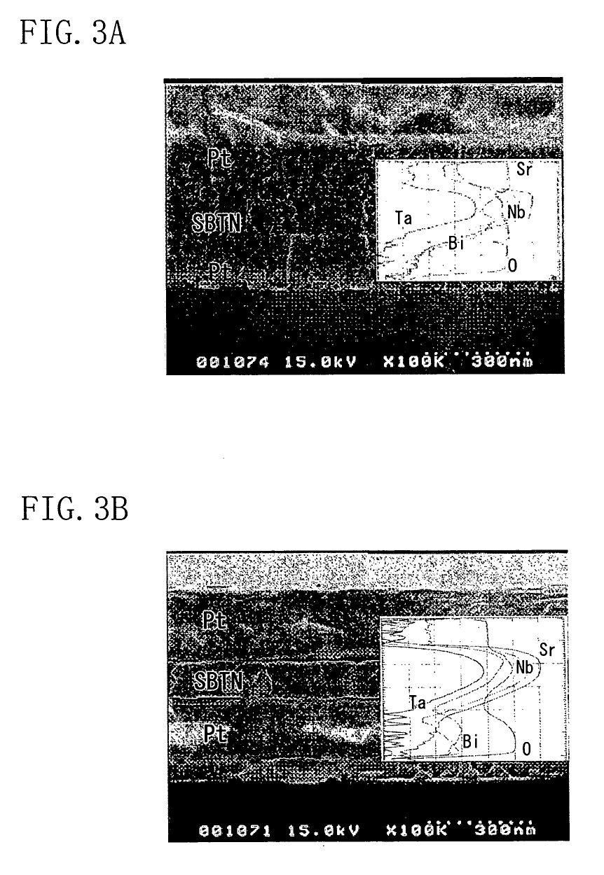

FIG. 3A shows the thicknesswise profile of composition of elements constituting the ferroelectric film of the actually fabricated ferroelectric capacitor according to the first embodiment. The ferroelectric film (SBTN) shown in FIG. 3A is formed, as one example, so that 10 nm-thick Sr_{0.8}Bi_{2.54}Ta₂O_{9.61} is applied, 80 nm-thick Sr_{0.7}Ba_{0.1}Bi₂La_{0.14}Ta₂O_{9.01} is applied, and then 10 nm-thick Sr_{0.8}Bi_{2.54}Ta₂O_{9.61} is applied. This formation is conducted by a metal organic decomposition method. FIG. 3B shows the thicknesswise profile of composition of elements constituting the ferroelectric film of the actually fabricated ferroelectric capacitor according to the conventional example.

As is apparent from FIGS. 3A and 3B, it is found that as compared with the thicknesswise profile of composition of the elements constituting the ferroelectric capacitor in FIG. 3B according to the conventional example, in the ferroelectric capacitor in FIG. 3A according to the first embodiment, Bi deficiency is made up for around the interface between the lower electrode and the ferroelectric film, formation of a so-called degraded layer around the interface is suppressed, and thereby factors in inhibiting polarization reversal are compensated. That is to say, of the elements constituting the ferroelectric film, the content of Bi element with a relatively high volatility has a smooth distribution in the thickness direction of the ferroelectric film, and the content of Bi element is locally minimum around the center of the thickness, and locally maximum around the interfaces between the ferroelectric film and the lower electrode, and between the ferroelectric film and the upper electrode.

The ferroelectric film is made of SBTN having a bismuth-layered ferroelectric crystal structure. Alternatively, the ferroelectric film may be made of a Pb-containing ferroelectric crystal structure represented by ABO₃ (where A and B are metal).

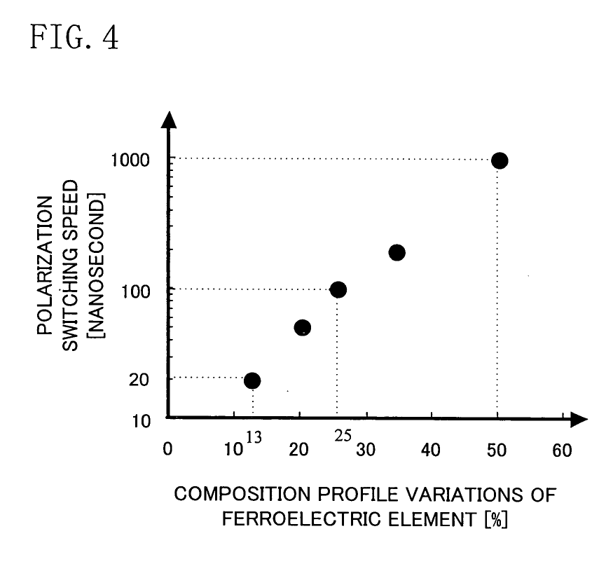

FIG. 4 shows the relation between variations (%) in composition profile of elements constituting the ferroelectric film of the ferroelectric capacitor and the polarization switching speed (nanosecond) of the ferroelectric capacitor according to the first embodiment. In FIG. 4, variations in composition profile in abscissa indicate the value of change in variations in the thicknesswise profile of composition of elements constituting the ferroelectric film formed on the lower electrode in the ferroelectric capacitor, which is obtained by changing the amount of oxygen gas added in forming the lower electrode, and the ordinate plots the polarization switching speed (nanosecond) of the ferroelectric capacitor associated with that value. The value of variations in composition profile plotted in abscissa is calculated by thicknesswise integration in which the maximum of the SIMS (Secondary Ion Mass Spectroscopy) profile of each thickness shown in FIG. 3A is considered as 100%.

As is apparent from FIG. 4, it is found that with the ferroelectric capacitor according to the first embodiment, when the thicknesswise profile of composition of elements constituting the ferroelectric film has variations of 50% or lower, the ferroelectric capacitor using this film can accomplish a polarization switching time of 1 μs or less. The thickness of the ferroelectric SBTN employed in this case is 240 nm. Likewise, it is found that when variations in composition profile are 25% or lower, the ferroelectric capacitor using this film can accomplish a polarization switching time of 100 ns or less. The thickness of the ferroelectric SBTN employed in this case is 100 nm. Also, it is found that when variations in composition profile are 13% or lower, the ferroelectric capacitor using this film can accomplish a polarization switching time of 20 ns or less. The thickness of the ferroelectric SBTN employed in this case is 60 nm.

As described above, with the present invention, of the elements constituting the ferroelectric film, the content of the element with a relatively high volatility has a smooth distribution in the thickness direction of the ferroelectric film, and the content of that element is locally minimum around the center of the thickness, and locally maximum around the interfaces between the ferroelectric film and the lower electrode and between the ferroelectric film and the upper electrode. Simultaneously with these, variations in composition profile of the elements constituting the ferroelectric film are further decreased. In the manner described above, high-speed operation of the ferroelectric capacitor can be provided.

### Second Embodiment

A ferroelectric capacitor and its fabrication method according to a second embodiment of the present invention will be described below.

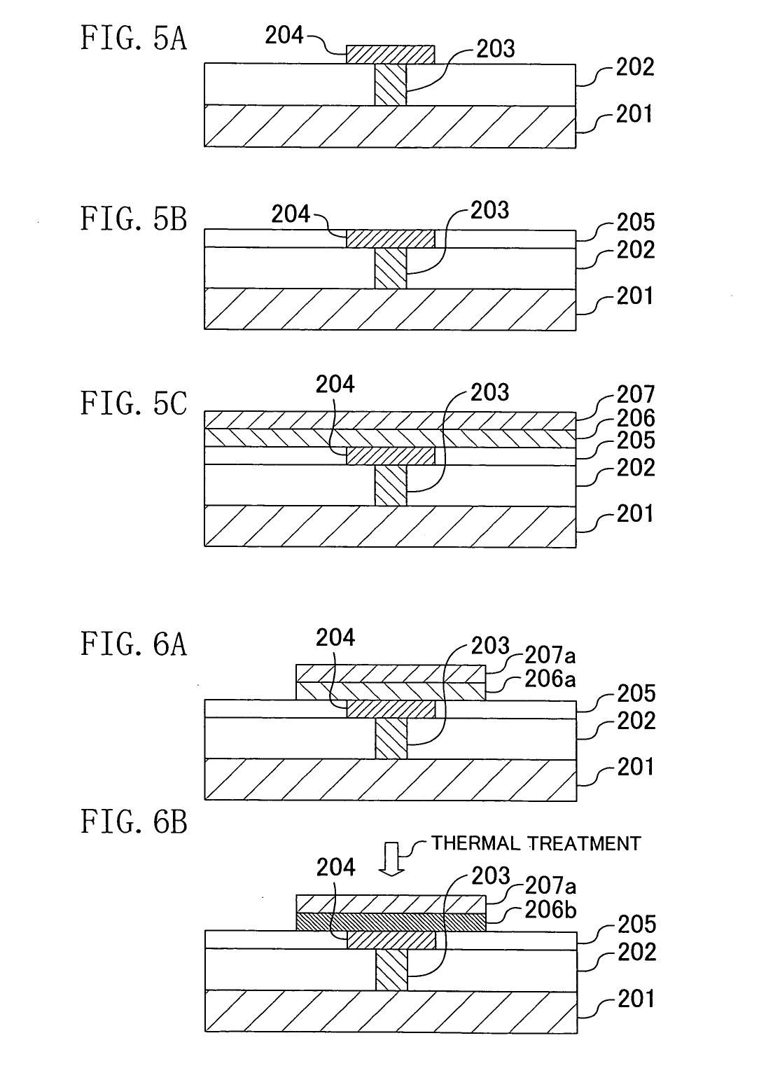

FIGS. 5A to 5C and 6A and 6B are sectional views showing the fabrication method of the ferroelectric capacitor according to the second embodiment of the present invention in the order of its fabrication process steps.

Referring to FIG. SA, on a semiconductor substrate 201 with memory cell transistors (not shown) and the like formed thereon, a first interlayer insulating film 202 is formed which is made of, for example, a BPSG (SiO₂ with B, P, and the like added therein) film. Subsequently, the first interlayer insulating film 202 is formed with a first contact plug 203 of tungsten, polysilicon, or the like whose bottom end reaches the top surface of the semiconductor substrate 201. Then, a lower electrode 204 made by sequentially stacking a barrier layer and a noble metal layer in this order is formed on the first interlayer insulating film 202. The barrier layer is composed of one or more layers selected from, for example, IrO, Ir, TiAlN, and TiN and functions as an oxygen barrier. The bottom surface of the barrier layer is connected to the top end of the first contact plug 203. The noble metal layer promotes crystal growth of a ferroelectric film that will be described later. Note that the lower electrode 204 is patterned to cover the first contact plug 203.

In this process, in forming at least a portion of the lower electrode 204 coming into contact with a ferroelectric film 206 to be hereinafter described, the portion is formed by sputtering under the condition of, for example, a substrate temperature of 200° C. or higher and an electrical power of 2 kW or lower. Thereby, an upper portion of the lower electrode 204 is formed to have a uniform orientation. This in turn decreases variations in orientation of the ferroelectric film 206 to be formed on the lower electrode 204.

Next, as shown in FIG. 5B, on the first interlayer insulating film 202, a buried insulating film made of SiO₂, O₃TEOS, or the like is formed to cover the lower electrode 204, and then CMP is carried out to expose the top surface of the lower electrode 204. Thereby, the buried insulating film 205 surrounding the lower electrode 204 is formed on the first interlayer insulating film 202. Although the lower electrode 204 is buried in the insulating film in the second embodiment, it is not limited to this structure.

As shown in FIG. 5C, a ferroelectric film 206 and a conductive film 207 made of one or more layers selected from Pt, Ir, and IrO are sequentially formed from bottom to top on the lower electrode 204 and the buried insulating film 205. In this step, the ferroelectric film 206 is to be formed on the lower electrode 204 with decreased variations in orientation, so that the formed ferroelectric film 206 also has decreased variations in orientation. Alternatively, the ferroelectric film 206 may be formed by the following procedure. First, a first ferroelectric film is formed which contains a too large amount of relatively high volatile element of the elements constituting the ferroelectric film (at least so that the content of that element is greater than the stoichiometric content thereof), and on the first ferroelectric film, a second ferroelectric film is formed which contains a too small amount of relatively high volatile element of the elements constituting the ferroelectric film (at least so that the content of that element is smaller than the stoichiometric content thereof). Finally, on the second ferroelectric film, a third ferroelectric film is formed which contains a too large amount of relatively high volatile element of the elements constituting the ferroelectric film (at least so that the content of that element is greater than the stoichiometric content thereof), thereby forming the ferroelectric film 206. Thereafter, calcination by rapid thermal processing (RTP) is performed for the purpose of producing nuclei serving as base points for crystal growth.

Next, as shown in FIG. 6A, the ferroelectric film 206a and the conductive film 207 are patterned to form a ferroelectric film 206a covering the top surface of the lower electrode 204 and an upper electrode 207a. Although the ferroelectric film 206a and the conductive film 207 are patterned using the same mask in this step, the patterning may be conducted using different masks.

Next, as shown in FIG. 6B, a thermal treatment for crystallizing the ferroelectric film 206a is performed to form the crystallized ferroelectric film 206b. In the manner described above, a ferroelectric capacitor formed of the lower electrode 204, the ferroelectric film 206b, and the upper electrode 207a is fabricated. The above description has been made of the case where the thermal treatment is performed twice, specifically, immediately after coating of the ferroelectric film 206 (see FIG. 5C) and during the step shown in FIG. 6B. Alternatively, it is sufficient to perform the thermal treatment at least once in any one of steps after coating of the ferroelectric film 206. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 207a. Then, on the second interlayer insulating film, an interconnect (a bit line) made of an Al/TiN/Ti stacked film is formed whose bottom surface is connected to the top end of the second contact plug.

As described above, with the second embodiment of the present invention, the orientation of the portion of the lower electrode coming into contact with the ferroelectric film can be made uniform to decrease variations in orientation of the ferroelectric film formed on the lower electrode. Therefore, degradation in polarization switching characteristics of the ferroelectric film can be prevented.

Herein, the effects exerted by the second embodiment of the present invention will be described in a concrete manner.

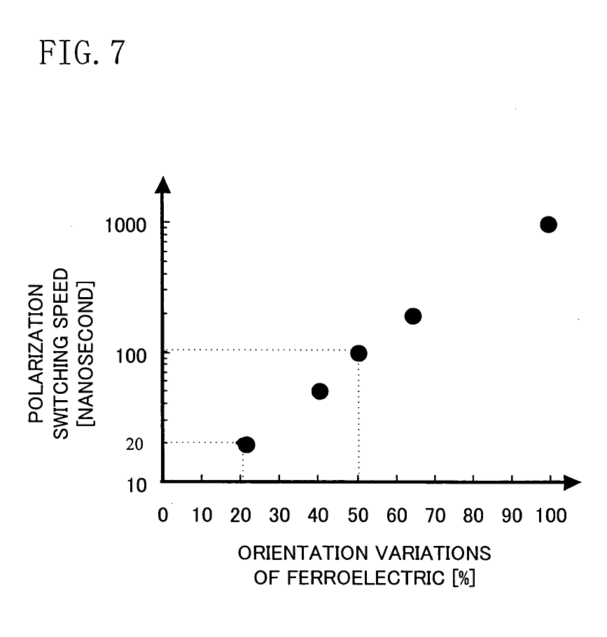

FIG. 7 shows the relation between variations (%) in orientation of the ferroelectric film and the polarization switching speed (nanosecond) of the ferroelectric capacitor according to the second embodiment. The result illustrated in FIG. 7 is obtained from the ferroelectric capacitor actually fabricated according to the second embodiment, and specifically the capacitor is fabricated on the following condition. To be more specific, the lower electrode 204 shown in FIG. 5A is fabricated, as one example, by sputtering under the condition of a substrate temperature of 300° C. and an electrical power of 2 kW (note that FIG. 7 shows the result obtained so that the sputtering is conducted under various sputtering conditions using the above-mentioned condition, that is, a substrate temperature of 300° C. and an electrical power of 2 kW, to change variations in orientation of the ferroelectric film). The ferroelectric film 206 shown in FIG. 5C is formed, as one example, by the following procedure. Using a metal organic decomposition method, a ferroelectric solution made of Sr_{0.8}Bi_{2.54}Ta₂O_{9.61} with a too large amount of bismuth added therein is applied to have a thickness of 10 nm, a ferroelectric solution made of Sr_{0.7}Ba_{0.1}Bi₂La_{0.14}Ta₂O_{9.01} with a too small amount of bismuth is applied to have a thickness of 80 nm, and then a Sr_{0.8}Bi_{2.54}Ta₂O_{9.61} is applied to have a thickness of 10 nm, thereby forming the ferroelectric film 206.

As is apparent from FIG. 7, it is found that with the ferroelectric capacitor of the second embodiment, when variations in orientation of the ferroelectric film are 100% or lower, the ferroelectric capacitor using this film can accomplish a polarization switching time of the ferroelectric film of 1 μs or less. Note that variations in orientation of 100% mean a randomly oriented state. The thickness of the ferroelectric SBTN employed in this case is 240 nm. Likewise, it is found that when variations in orientation are 50% or lower, the ferroelectric capacitor using this film can accomplish a polarization switching time of 100 ns or less. The thickness of the ferroelectric SBTN employed in this case is 100 nm. Also, it is found that when variations in orientation are 20% or lower, the ferroelectric capacitor using this film can accomplish a polarization switching time of 20 ns or less. The thickness of the ferroelectric SBTN employed in this case is 60 nm.

As described above, with the present invention, variations in orientation of the ferroelectric film constituting the ferroelectric capacitor are made smaller to eliminate an edge slope of the variation distribution which will induce degradation in the polarization switching time of the ferroelectric capacitor. Therefore, high-speed operation of the ferroelectric capacitor can be provided.

### Third Embodiment

A third embodiment of the present invention will describe a fabrication method of a ferroelectric capacitor which can decrease variations in composition profile of the elements constituting the ferroelectric film of the ferroelectric capacitor, as well as variations in orientation of the ferroelectric film. This method is carried out for the purpose of decreasing degradation in polarization switching characteristics by reducing the polarization switching time of the ferroelectric film as described above in the first and second embodiments. In the third embodiment, the description is divided according to materials constituting the ferroelectric film.

### —Ferroelectric Film made of SBTN—

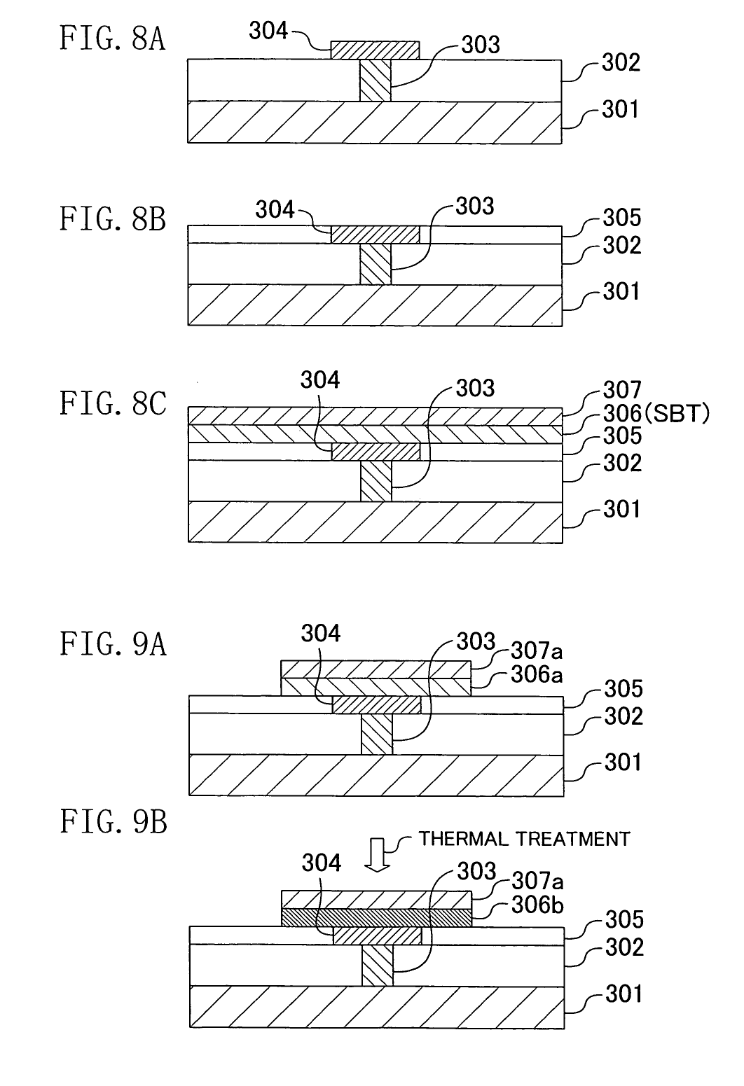

FIGS. 8A to 8C and 9A and 9B are sectional views showing a fabrication method of a ferroelectric capacitor made of SBTN according to the third embodiment of the present invention in the order of its fabrication process steps.

Referring to FIG. 8A, on a semiconductor substrate 301 with memory cell transistors (not shown) and the like formed thereon, a first interlayer insulating film 302 is formed which is made of, for example, a BPSG (SiO₂ with B, P, and the like added therein) film. Subsequently, the first interlayer insulating film 302 is formed with a first contact plug 303 of tungsten, polysilicon, or the like whose bottom end reaches the top surface of the semiconductor substrate 301. Then, a lower electrode 304 made by sequentially stacking a barrier layer and a noble metal layer in this order is formed on the first interlayer insulating film 302. The barrier layer is composed of one or more layers selected from, for example, IrO, Ir, TiAlN, and TiN and functions as an oxygen barrier. The bottom surface of the barrier layer is connected to the top end of the first contact plug 303. The noble metal layer promotes crystal growth of a ferroelectric film that will be described later. Note that the lower electrode 304 is patterned to cover the first contact plug 303.

Next, as shown in FIG. 8B, on the first interlayer insulating film 302, a buried insulating film made of SiO₂, O₃TEOS, or the like is formed to cover the lower electrode 304, and then CMP is carried out to expose the top surface of the lower electrode 304. Thereby, the buried insulating film 305 surrounding the lower electrode 304 is formed on the first interlayer insulating film 302. Although the lower electrode 304 is buried in the insulating film in the third embodiment, it is not limited to this structure.

As shown in FIG. 8C, a ferroelectric film 306 and a conductive film 307 made of one or more layers selected from Pt, Ir, and IrO are sequentially formed from bottom to top on the lower electrode 304 and the buried insulating film 305.

In this formation step, the ferroelectric film 306 is formed by the following procedure. Using a spin coat method, a ferroelectric solution made of Sr_{0.8}Bi_{2.54}Ta₂O_{9.61} with a too large amount of bismuth added therein is applied onto the lower electrode 304 and the buried insulating film 305 to have a thickness of 10 nm, a ferroelectric solution made of Sr_{0.7}Ba_{0.1}Bi₂La_{0.14}Ta₂O_{9.01} with a too small amount of bismuth contained therein is applied to have a thickness of 70 nm, and then a ferroelectric solution made of Sr_{0.8}Bi_{2.54}Ta₂O_{9.61} with a too large amount of bismuth added therein is applied to have a thickness of 10 nm. Thereafter, wafer baking is conducted at about a temperature at which solvent volatilizes (150 to 300° C.) to form the ferroelectric film 306. Subsequently, calcination by rapid thermal processing (RTP) is performed for the purpose of producing nuclei serving as base points for crystal growth. Although the temperature for nucleus production differs depending on the type of ferroelectric material, an SBTN material is calcined at about 650° C.

As shown in FIG. 9A, the ferroelectric film 306a and the conductive film 307 are patterned to form a ferroelectric film 306a covering the top surface of the lower electrode 304 and an upper electrode 307a. Although the ferroelectric film 306a and the conductive film 307 are patterned using the same mask in this step, the patterning may be conducted using different masks.

Next, as shown in FIG. 9B, a thermal treatment for crystallizing the ferroelectric film 306a is performed to form the crystallized ferroelectric film 306b. Since the target in this step is the ferroelectric film 306a of SBTN, the thermal treatment is performed at about 650 to 800° C. The above description has been made of the case where the thermal treatment is performed twice, specifically, immediately after coating of the ferroelectric film 306 (see FIG. 8C) and during the step shown in FIG. 9B. Alternatively, it is sufficient to perform the thermal treatment at least once in any one of steps after coating of the ferroelectric film 306. In the manner described above, a ferroelectric capacitor formed of the lower electrode 304, the ferroelectric film 306b, and the upper electrode 307a is fabricated. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 307a. Then, on the second interlayer insulating film, an interconnect (a bit line) made of an Al/TiN/Ti stacked film is formed whose bottom surface is connected to the top end of the second contact plug.

With the manner described above, the ferroelectric film formed to contain a too large amount of Bi can suppress, even after the thermal treatment, deficiency of Bi constituting the ferroelectric film, and inhibit creation of an interface layer located around the electrode and making no contribution to the polarization switching characteristics of the ferroelectric film. This decreases variations in the thicknesswise profile of composition constituting the ferroelectric film of the ferroelectric capacitor, and concurrently variations in orientation of the ferroelectric film. Therefore, the polarization switching characteristics of the ferroelectric film can be prevented from being degraded due to deficiency of Bi constituting the ferroelectric film.

### —Ferroelectric Film made of PZT—

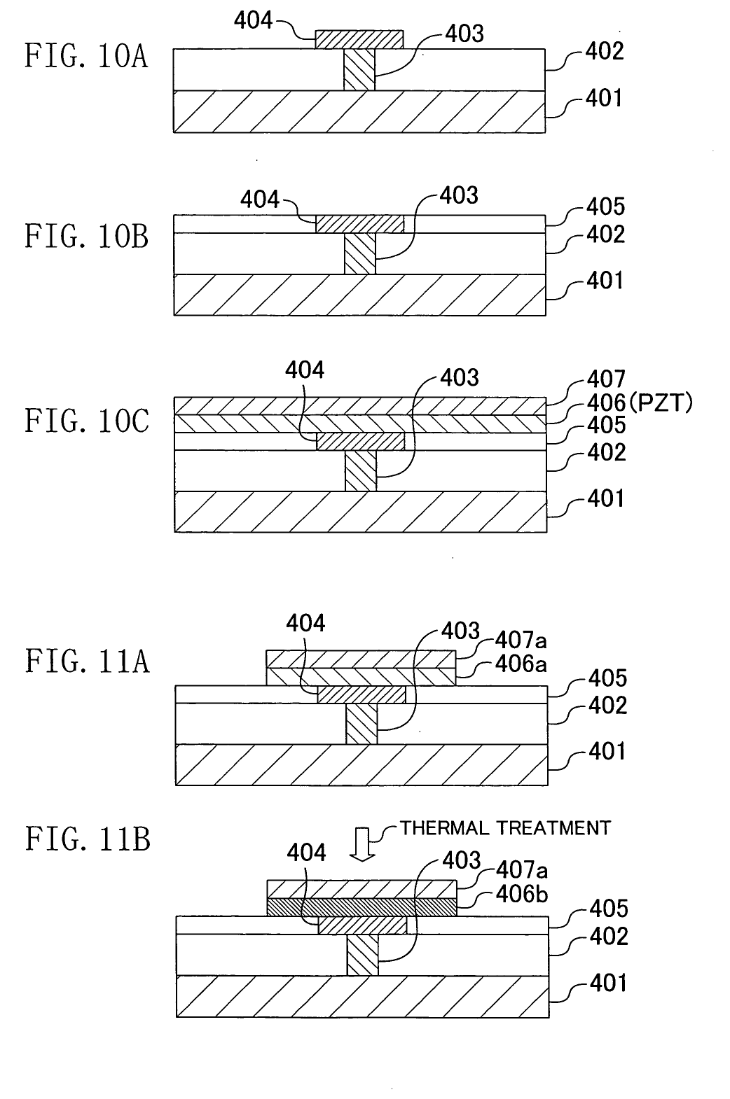

FIGS. 10A to 10C and 11A and 11B are sectional views showing a fabrication method of a ferroelectric capacitor made of PZT according to the third embodiment of the present invention in the order of its fabrication process steps.

Referring to FIG. 10A, on a semiconductor substrate 401 with memory cell transistors (not shown) and the like formed thereon, a first interlayer insulating film 402 is formed which is made of, for example, a BPSG (SiO₂ with B, P, and the like added therein) film. Subsequently, the first interlayer insulating film 402 is formed with a first contact plug 403 of tungsten, polysilicon, or the like whose bottom end reaches the top surface of the semiconductor substrate 401. Then, a lower electrode 404 made by sequentially stacking a barrier layer and a noble metal layer in this order is formed on the first interlayer insulating film 402. The barrier layer is composed of one or more layers selected from, for example, IrO, Ir, TiAlN, and TiN and functions as an oxygen barrier. The bottom surface of the barrier layer is connected to the top end of the first contact plug 403. The noble metal layer promotes crystal growth of a ferroelectric film that will be described later. Note that the lower electrode 404 is patterned to cover the first contact plug 403.

Next, as shown in FIG. 10B, on the first interlayer insulating film 402, a buried insulating film made of SiO₂, O₃TEOS, or the like is formed to cover the lower electrode 404, and then CMP is carried out to expose the top surface of the lower electrode 404. Thereby, the buried insulating film 405 surrounding the lower electrode 404 is formed on the first interlayer insulating film 402. Although the lower electrode 404 is buried in the insulating film in the third embodiment, it is not limited to this structure.

As shown in FIG. 10C, a ferroelectric film 406 and a conductive film 407 made of one or more layers selected from Pt, Ir, and IrO are sequentially formed from bottom to top on the lower electrode 404 and the buried insulating film 405.

In this formation step, the ferroelectric film 406 is formed by the following procedure. Using a spin coat method, a ferroelectric solution made of Pb_{1.5}Ca_{0.1}Zr_{0.47}Ti_{0.53}O_{3.6} with a too large amount of Pb added therein is applied onto the lower electrode 404 and the buried insulating film 405 to have a thickness of 5 nm, a ferroelectric solution made of Pb_{0.95}Zr_{0.47}Ti_{0.53}O_{2.95} with a too small amount of Pb contained therein is applied to have a thickness of 40 nm, and then a ferroelectric solution made of Pb_{1.5}Ca_{0.1}Zr_{0.47}Ti_{0.53}O_{3.6} is applied to have a thickness of 5 nm. Thereafter, wafer baking is conducted at about a temperature at which solvent volatilizes (150 to 300° C.) to form the ferroelectric film 406. Subsequently, calcination by rapid thermal processing (RTP) is performed for the purpose of producing nuclei serving as base points for crystal growth. Although the temperature for nucleus production differs depending on the type of ferroelectric material, a PZT material is calcined at about 450° C.

Next, as shown in FIG. 11A, the ferroelectric film 406a and the conductive film 407 are patterned to form a ferroelectric film 406a covering the top surface of the lower electrode 404 and an upper electrode 407a. Although the ferroelectric film 406a and the conductive film 407 are patterned using the same mask in this step, the patterning may be conducted using different masks.

Next, as shown in FIG. 11B, a thermal treatment for crystallizing the ferroelectric film 406a is performed to form the crystallized ferroelectric film 406b. Since the target in this step is the ferroelectric film 406a of PZT, the thermal treatment is performed at about 450 to 650° C. The above description has been made of the case where the thermal treatment is performed twice, specifically, immediately after coating of the ferroelectric film 406 (see FIG. 10C) and during the step shown in FIG. 11B. Alternatively, it is sufficient to perform the thermal treatment at least once in any one of steps after coating of the ferroelectric film 406. In the manner described above, a ferroelectric capacitor formed of the lower electrode 404, the ferroelectric film 406b, and the upper electrode 407a is fabricated. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 407a. Then, on the second interlayer insulating film, an interconnect (a bit line) made of an Al/TiN/Ti stacked film is formed whose bottom surface is connected to the top end of the second contact plug.

With the manner described above, the ferroelectric film formed to contain a too large amount of Pb can suppress, even after the thermal treatment, deficiency of Pb constituting the ferroelectric film, and inhibit creation of an interface layer located around the electrode and making no contribution to the polarization switching characteristics of the ferroelectric film. This decreases variations in the thicknesswise profile of composition constituting the ferroelectric film of the ferroelectric capacitor, and concurrently variations in orientation of the ferroelectric film. Therefore, the polarization switching characteristics of the ferroelectric film can be prevented from being degraded due to deficiency of Pb constituting the ferroelectric film.

### —Ferroelectric Film made of BLT—

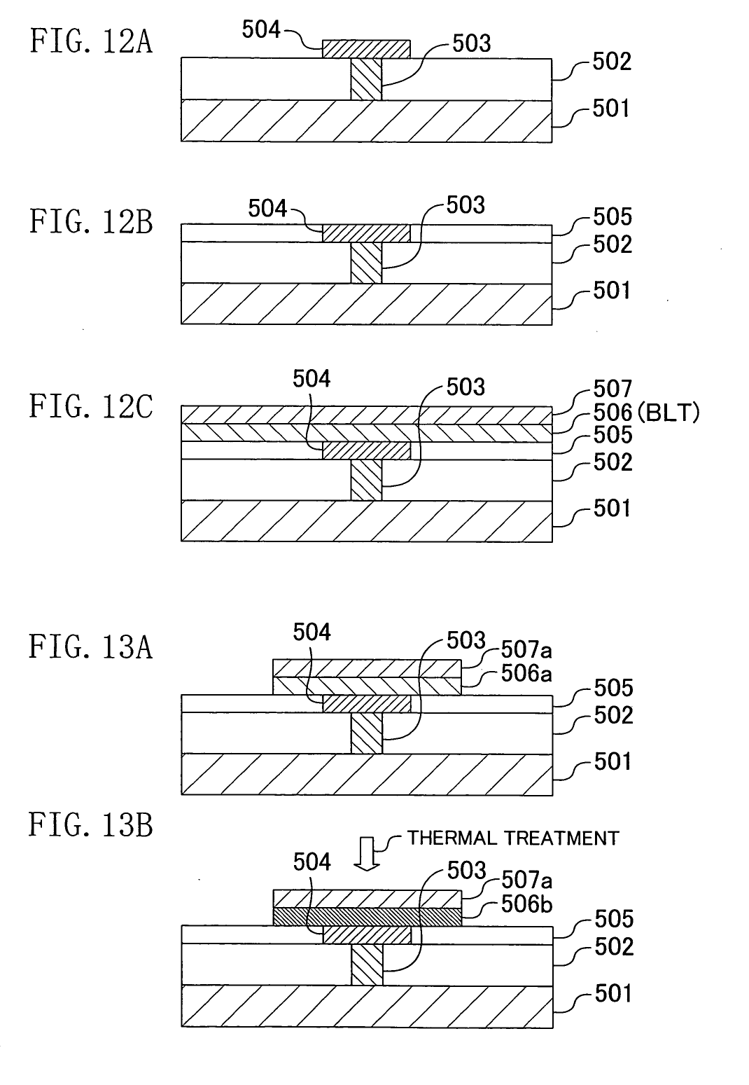

FIGS. 12A to 12C and 13A and 13B are sectional views showing a fabrication method of a ferroelectric capacitor made of BLT according to the third embodiment of the present invention in the order of its fabrication process steps.

Referring to FIG. 12A, on a semiconductor substrate 501 with memory cell transistors (not shown) and the like formed thereon, a first interlayer insulating film 502 is formed which is made of, for example, a BPSG (SiO₂ with B, P, and the like added therein) film. Subsequently, the first interlayer insulating film 502 is formed with a first contact plug 503 of tungsten, polysilicon, or the like whose bottom end reaches the top surface of the semiconductor substrate 501. Then, a lower electrode 504 made by sequentially stacking a barrier layer and a noble metal layer in this order is formed on the first interlayer insulating film 502. The barrier layer is composed of one or more layers selected from, for example, IrO, Ir, TiAlN, and TiN and functions as an oxygen barrier. The bottom surface of the barrier layer is connected to the top end of the first contact plug 503. The noble metal layer promotes crystal growth of a ferroelectric film that will be described later. Note that the lower electrode 504 is patterned to cover the first contact plug 503.

Next, as shown in FIG. 12B, on the first interlayer insulating film 502, a buried insulating film made of SiO₂, O₃TEOS, or the like is formed to cover the lower electrode 504, and then CMP is carried out to expose the top surface of the lower electrode 504. Thereby, the buried insulating film 505 surrounding the lower electrode 504 is formed on the first interlayer insulating film 502. Although the lower electrode 504 is buried in the insulating film in the third embodiment, it is not limited to this structure.

As shown in FIG. 12C, a ferroelectric film 506 and a conductive film 507 made of one or more layers selected from Pt, Ir, and IrO are sequentially formed from bottom to top on the lower electrode 504 and the buried insulating film 505.

In this formation step, the ferroelectric film 506 is formed by the following procedure. Using a spin coat method, a ferroelectric solution made of Bi_{4.4}La_{0.25}Ti₃O_{12.975} with a too large amount of Bi added therein is applied onto the lower electrode 504 and the buried insulating film 505 to have a thickness of 8 nm, a ferroelectric solution made of Bi_{3.9}La_{0.25}Ti₃O_{12.225} with a too small amount of Bi contained therein is applied to have a thickness of 60 nm, and then a ferroelectric solution made of Bi_{4.4}La_{0.25}Ti₃O_{12.975} with a too large amount of Bi added therein is applied to have a thickness of 7 nm. Thereafter, wafer baking is conducted at about a temperature at which solvent volatilizes (150 to 300° C.) to form the ferroelectric film 506. Subsequently, calcination by rapid thermal processing (RTP) is performed for the purpose of producing nuclei serving as base points for crystal growth. Although the temperature for nucleus production differs depending on the type of ferroelectric material, a BLT material is calcined at about 500° C.

Next, as shown in FIG. 13A, the ferroelectric film 506a and the conductive film 507 are patterned to form a ferroelectric film 506a covering the top surface of the lower electrode 504 and an upper electrode 507a. Although the ferroelectric film 506a and the conductive film 507 are patterned using the same mask in this step, the patterning may be conducted using different masks.

Next, as shown in FIG. 13B, a thermal treatment for crystallizing the ferroelectric film 506a is performed to form the crystallized ferroelectric film 506b. Since the target in this step is the ferroelectric film 506a of BLT, the thermal treatment is performed at about 500 to 700° C. The above description has been made of the case where the thermal treatment is performed twice, specifically, immediately after coating of the ferroelectric film 506 (see FIG. 12C) and during the step shown in FIG. 13B. Alternatively, it is sufficient to perform the thermal treatment at least once in any one of steps after coating of the ferroelectric film 506. In the manner described above, a ferroelectric capacitor formed of the lower electrode 504, the ferroelectric film 506b, and the upper electrode 507a is fabricated. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 507a. Then, on the second interlayer insulating film, an interconnect (a bit line) made of an Al/TiN/Ti stacked film is formed whose bottom surface is connected to the top end of the second contact plug.

With the manner described above, the ferroelectric film formed to contain a too large amount of Bi can suppress, even after the thermal treatment, deficiency of Bi constituting the ferroelectric film, and inhibit creation of an interface layer located around the electrode and making no contribution to the polarization switching characteristics of the ferroelectric film. This decreases variations in the thicknesswise profile of composition of the elements constituting the ferroelectric film of the ferroelectric capacitor, and concurrently variations in orientation of the ferroelectric film. Therefore, the polarization switching characteristics of the ferroelectric film can be prevented from being degraded due to deficiency of Bi constituting the ferroelectric film.

In the embodiment shown above, Ba is used as a substitute for the A-site metal of the ferroelectric, and La is used as a material serving as a substitute for Bi. However, the present invention is not limited to the examples shown above.

In the first to third embodiments shown above, description has been made of the structure in which the lower electrode serves as a capacitance definition unit, that is, the lower electrode is smaller than the upper electrode. Alternatively, it is acceptable that the capacitor has the structure in which the upper electrode serves as a capacitance definition unit. In addition, in order to prevent degradation of the ferroelectric film due to hydrogen, the ferroelectric capacitor may be designed to be surrounded by a hydrogen barrier film, that is, for example, the ferroelectric capacitor may be designed so that a first hydrogen barrier film (SiN, SiON, TiAlO, Al₂O₃) formed below the ferroelectric capacitor and a second hydrogen barrier film (SiN, SiON, TiAlO, Al₂O₃) formed to cover the upper portion of the ferroelectric capacitor cover the left, right, top and bottom of the ferroelectric capacitor.

In the embodiments mentioned above, description has been made of the case where a ferroelectric solution of Sr_{0.8}Bi_{2.54}Ta₂O_{9.61} and a ferroelectric solution of Sr_{0.7}Ba_{0.1}Bi₂La_{0.14}Ta₂O_{9.01} are used for formation of, for example, the ferroelectric film made of SBT. Alternatively, a ferroelectric solution of Sr_{0.7}Ba_{0.2}Bi_{2.64}Ta₂O_{9.61} and a ferroelectric solution of Sr_{0.8}Bi_{1.99}La_{0.1}Ta₂O_{9.01} may be used therefor. As long as the composition is adjusted to compensate Bi deficiency at the interface with the electrode according to a thermal treatment, solution is not limited to the above-listed ones. The same holds for the case where the ferroelectric film made of PZT or BLT is formed.

It is sufficient that metal such as Ba or La capable of attaining low coercive voltage of Vc is present in either one of the layer containing a too large amount of Bi and the layer containing a too small amount of Bi. Description has been made of the case of conducting doping with metal such as La or Ca capable of attaining the characteristics or reliability of the ferroelectric capacitor, but the present invention is not limited to the above-shown examples. Even though doping with that metal is eliminated, no influence is imposed on the effects of the present invention.

The thickness of the ferroelectric film is not limited to the above-shown examples. It is sufficient to set the thickness to accomplish a desired polarization switching speed.

The present invention is useful for a ferroelectric capacitor with a ferroelectric film used as a capacitor insulating film and a ferroelectric memory device using the film.

What is claimed is:

1. A ferroelectric capacitor comprising: a lower electrode; a ferroelectric film formed on the lower electrode; and an upper electrode formed on the ferroelectric film,
wherein in the thickness direction of the ferroelectric film, variations in composition profile of elements constituting the ferroelectric film are 50% or lower, and
the polarization switching time of the ferroelectric film is 1 μs or less.

2. The capacitor of claim 1,
wherein variations in the composition profile are 25% or lower, and
the polarization switching time is 100 ns or less.

3. The capacitor of claim 1,
wherein variations in the composition profile are 13% or lower, and the polarization switching time is 20 ns or less.

4. A ferroelectric capacitor comprising: a lower electrode; a ferroelectric film formed on the lower electrode; and an upper electrode formed on the ferroelectric film,
wherein variations in orientation of the ferroelectric film are 100% or lower, and the polarization switching time of the ferroelectric film is 1 μs or less.

5. The capacitor of claim 4,
wherein variations in orientation of the ferroelectric film are 50% or lower, and
the polarization switching time of the ferroelectric film is 100 ns or less.

6. The capacitor of claim 4,
wherein variations in orientation of the ferroelectric film are 20% or lower, and
the polarization switching time of the ferroelectric film is 20 ns or less.

7. A ferroelectric capacitor comprising: a lower electrode; a ferroelectric film formed on the lower electrode; and an upper electrode formed on the ferroelectric film,
wherein of elements constituting the ferroelectric film, the content of an element with a relatively high volatility has a smooth distribution in the thickness direction of the ferroelectric film,
the content of the element with a relatively high volatility is locally minimum around the center of the thickness of the ferroelectric film, and
the content of the element with a relatively high volatility is locally maximum around the interfaces between the ferroelectric film and the lower electrode and between the ferroelectric film and the upper electrode.

8. The capacitor of claim 7,
wherein the ferroelectric film has a Pb-containing ferroelectric crystal structure represented by (Bi₂O₂)²⁺ (Aₘ₋₁BₘO₃ₘ₊₁)²⁻ (where A and B represent metal), and
the element with a relatively high volatility is Pb.

9. The capacitor of claim 7,
wherein the ferroelectric film has a bismuth-layered ferroelectric crystal structure, and
the element with a relatively high volatility is Bi.

10. A method for fabricating a ferroelectric capacitor which comprises: a lower electrode; a ferroelectric film formed on the lower electrode and having a Pb-containing ferroelectric crystal structure represented by (Bi₂O₂)²⁺ (Aₘ₋₁BₘO₃ₘ₊₁)²⁻ (where A and B represent metal); and an upper electrode formed on the ferroelectric film,
wherein formation of the ferroelectric film comprises:
a first step of forming, on the lower electrode, a first ferroelectric film containing a greater number of Pb in content than the stoichiometric content;
a second step of forming, on the first ferroelectric film, a second ferroelectric film containing a smaller number of Pb in content than the stoichiometric content; and
a third step of forming, on the second ferroelectric film, a third ferroelectric film containing a greater number of Pb in content than the stoichiometric content.

11. The method of claim 10,
wherein formation of the ferroelectric film further comprises, after the third step, the step of performing a thermal treatment at a temperature higher than the crystallization temperatures of the first, second, and third ferroelectric films.

12. A method for fabricating a ferroelectric capacitor which comprises: a lower electrode; a ferroelectric film formed on the lower electrode and having a Bi-containing ferroelectric crystal structure represented by (Bi₂O₂)²⁺ (Aₘ₋₁BₘO₃ₘ₊₁)²⁻ (where A and B represent metal); and an upper electrode formed on the ferroelectric film,
wherein formation of the ferroelectric film comprises:
a first step of forming, on the lower electrode, a first ferroelectric film containing a greater number of Bi in content than the stoichiometric content;
a second step of forming, on the first ferroelectric film, a second ferroelectric film containing a smaller number of Bi in content than the stoichiometric content; and
a third step of forming, on the second ferroelectric film, a third ferroelectric film containing a greater number of Bi in content than the stoichiometric content.

13. The method of claim 12,
wherein formation of the ferroelectric film further comprises, after the third step, the step of performing a thermal treatment at a temperature higher than the crystallization temperatures of the first, second, and third ferroelectric films.
